(19) United States
(12) Patent Application Publication
(10) Pub. No.: US 2026/0064069 A1
(43) Pub. Date: Mar. 5, 2026

(54) CIRCUIT BOARD AND IMAGE FORMING APPARATUS

(71) Applicant: CANON KABUSHIKI KAISHA, Tokyo (JP)

(72) Inventor: NORIAKI ADACHI, Chiba (JP)

(21) Appl. No.: 19/311,534

(22) Filed: Aug. 27, 2025

(30) Foreign Application Priority Data
Sep. 3, 2024 (JP) 2024-151594

(51) Int. Cl. G03G 15/00; G01R 19/00

(52) U.S. Cl. CPC G03G 15/80; G01R 19/0092; G03G 15/5004

(57) ABSTRACT

A circuit board includes a first surface including a first region in which a first electronic part is mountable, a second surface, which is different from the first surface, including a second region in which a second electronic part is mountable, a first connection portion, which is arranged on the first surface and to which a terminal of the first electronic part is connected, a first element arranged on the first surface, a second connection portion, which is arranged on the second surface and to which a terminal of the second electronic part is connected, a second element arranged on the second surface, a wiring pattern that connects the first element and the second element in parallel, and electrically connects both of the first element and the second element to the first connection portion and to the second connection portion.

### BACKGROUND

### Field of the Technology

The present disclosure relates to a circuit board on which electronic parts for operating constituent parts such as built-in actuators are mounted, and to an image forming apparatus, such as a printer, a copying machine, or a multifunction peripheral, including such a circuit board.

### Description of the Related Art

An image forming apparatus generally includes a plurality of circuit boards. On each circuit board, a plurality of electronic parts is mounted in accordance with the function to be implemented. The plurality of electronic parts includes an electronic part for performing a logic operation, an electronic part for performing drive control, and an electronic part for generating a power supply voltage. The electronic part on the circuit board is connected by a conductor wire (wiring pattern) such as a printed wiring line. The electronic part includes an integrated circuit and electronic elements, such as a resistor, a capacitor, and an inductor, which are connected to input/output terminals of the integrated circuit. An electronic part component is formed by these electronic parts.

The image forming apparatus prints an image on a sheet through a plurality of steps such as sheet conveyance, image formation, image transfer onto a sheet, and fixing of an image to the sheet. Accordingly, the image forming apparatus is required to control a wide variety of actuators, such as an optical sensor, a temperature sensor, a motor, and a solenoid. Japanese Patent Application Laid-open No. 2022-6639 discloses a circuit board for control mounted in an image forming apparatus. On the circuit board described in Japanese Patent Application Laid-open No. 2022-6639, a plurality of electronic parts for controlling the actuators are mounted. For example, a driver board for driving a motor includes, in order to control the motor appropriately, an integrated circuit (motor driver IC) for generating a motor drive signal based on a control signal input from a controller. Further, the circuit board for control itself is also provided as a plurality of circuit boards for control in the image forming apparatus.

### SUMMARY

A circuit board according to some embodiments of the present disclosure includes a first surface including a first region in which a first electronic part is mountable, a second surface, which is different from the first surface, including a second region in which a second electronic part is mountable, a first connection portion, which is arranged on the first surface and to which a terminal of the first electronic part is connected, a first element arranged on the first surface, a second connection portion, which is arranged on the second surface and to which a terminal of the second electronic part is connected, a second element arranged on the second surface, a wiring pattern that connects the first element and the second element in parallel, and electrically connects both of the first element and the second element to the first connection portion and to the second connection portion.

An image forming apparatus according to another embodiment of the present disclosure includes a circuit board, and an image forming part configured to perform a function related or included in forming image, wherein the circuit board includes a first surface including a first region in which a first electronic part is mountable, a second surface, which is different from the first surface, including a second region in which a second electronic part is mountable, a first connection portion, which is arranged on the first surface and to which a terminal of the first electronic part is connected, a first element arranged on the first surface, a second connection portion, which is arranged on the second surface and to which a terminal of the second electronic part is connected, a second element arranged on the second surface, and a wiring pattern that connects the first element and the second element in parallel, and electrically connects both of the first element and the second element to the first connection portion and to the second connection portion, and wherein the image forming part is configured to be controlled by one of the first electronic part or the second electronic part mounted on the circuit board.

Features of the present disclosure will become apparent from the following description of embodiments with reference to the attached drawings. The following description of embodiments is described by way of example.

### BRIEF DESCRIPTION OF THE DRAWINGS

FIG. 1 is a system configuration diagram of an image forming apparatus.

FIG. 2 is a configuration view of the image forming apparatus.

FIG. 3 is a functional block diagram of a circuit board.

FIG. 4 is an explanatory diagram of electronic part components.

FIG. 5 is an explanatory view of wiring patterns of the circuit board.

FIG. 6 is an explanatory view of wiring patterns of the circuit board in a comparative example.

FIG. 7 is a sectional view of a circuit board.

### DESCRIPTION OF THE EMBODIMENTS

Now, description is given of at least one embodiment of the present disclosure with reference to the accompanying drawings.

A part of electronic parts such as the motor driver IC varies in size, terminal arrangement, and the like depending on the manufacturer or a difference in specification. Accordingly, it is difficult for a circuit board to have wiring with a common foot pattern for different electronic parts. In view of the above, it is desired to provide a foot pattern corresponding to a plurality of electronic parts that implement the same function on one circuit board in advance so that the same function is implemented by switching mounting/unmounting of the electronic part.

Accordingly, as to circuit boards that can universally mount electronic parts with different specifications, it is desirable to consider appropriate wiring patterns.

### <Configuration of Image Forming Apparatus>

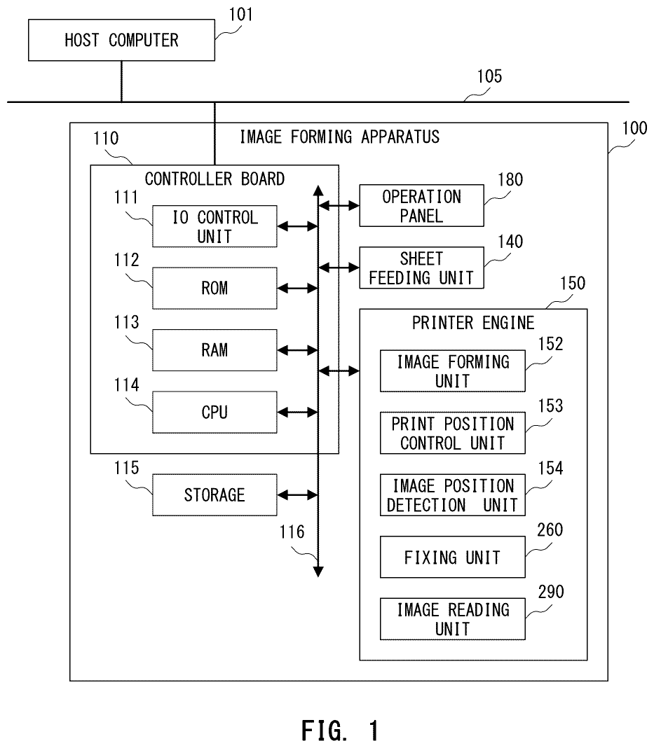

FIG. 1 is a system configuration diagram of an image forming apparatus including a circuit board according to at least one embodiment of the present disclosure. It should be understood that, unless otherwise described, an image forming apparatus 100 may be a system including a plurality of apparatus connected to each other via a network, as long as functions of the image forming apparatus 100 can be implemented.

The image forming apparatus 100 according to the at least one embodiment is connected to a host computer 101 via a network 105 so that communication is allowed therebetween. The network 105 includes a communication line such as a local area network (LAN), a wide area network (WAN), and a public communication line. A plurality of image forming apparatus 100 and a plurality of host computers 101 may be connected to the network 105. The host computer 101 generates a print job, and transmits the generated print job to the image forming apparatus 100 via the network 105.

The image forming apparatus 100 includes a controller board 110, a storage 115, a sheet feeding unit 140, a printer engine 150, and an operation panel 180. The controller board 110, the storage 115, the sheet feeding unit 140, the printer engine 150, and the operation panel 180 are connected to each other via a system bus 116 so that mutual communication is allowed therebetween.

The controller board 110 includes an I/O control unit 111, a read only memory (ROM) 112, a random access memory (RAM) 113, and a central processing unit (CPU) 114. The I/O control unit 111, the ROM 112, the RAM 113, and the CPU 114 are mounted on a circuit board. The controller board 110 functions as a main control unit of the image forming apparatus 100, and controls the operation of the entire image forming apparatus 100. The circuit board is, for example, a printed wiring board having printed wiring formed thereon.

The I/O control unit 111 controls communication to/from an external apparatus such as the host computer 101 via the network 105. The CPU 114 executes a computer program stored in the ROM 112 or the storage 115 to control an operation such as image forming processing to be performed by the image forming apparatus 100. Computer programs include a startup program, a control program, an operating system, etc. The startup program, the control program, and the operating system etc., are stored in the ROM 112 and the storage 115. The RAM 113 provides a work area used in a case where the CPU 114 executes processing, and performs storage of temporal data or the like. The storage 115 stores large-capacity data, such as image data or print data, on a temporary or long-term basis. For example, the storage 115 stores image data for generating an image for adjustment for use in adjusting an image forming condition. The storage 115 is a large-capacity storage device, such as a hard disk drive (HDD) or a solid state drive (SSD).

The operation panel 180 is a user interface including an input interface and an output interface. The input interface is, for example, key buttons and a touch panel. The output interface is a display, a speaker, and the like. The operation panel 180 receives an instruction or the like through the operation of the user and inputs the received instruction or the like to the CPU 114. The CPU 114 controls the operation of the image forming apparatus 100 in accordance with the instruction. Further, the operation panel 180 displays a state of the image forming apparatus 100 and various setting screens in accordance with the instruction from the CPU 114.

The sheet feeding unit 140 includes a sheet feeding device including one or more sheet feeding stages, and an entire conveying unit for conveying a sheet from one of the sheet feeding stages to a sheet discharging unit. The sheet feeding unit 140 feeds sheets one by one from the sheet feeding stage in accordance with the instruction from the CPU 114.

The printer engine 150 includes an image forming unit 152, a print position control unit 153, an image position detection unit 154, a fixing unit 260, and an image reading unit 290. The image forming unit 152 forms an image (toner image) on the sheet fed by the sheet feeding unit 140. The fixing unit 260 fixes the image (toner image) to the sheet. The image reading unit 290 reads the image for adjustment printed on the image. The image position detection unit 154 detects an image position on the sheet based on results of reading the image for adjustment by the image reading unit 290. The print position control unit 153 controls the position of the image to be formed on the sheet based on the image position detected by the image position detection unit 154.

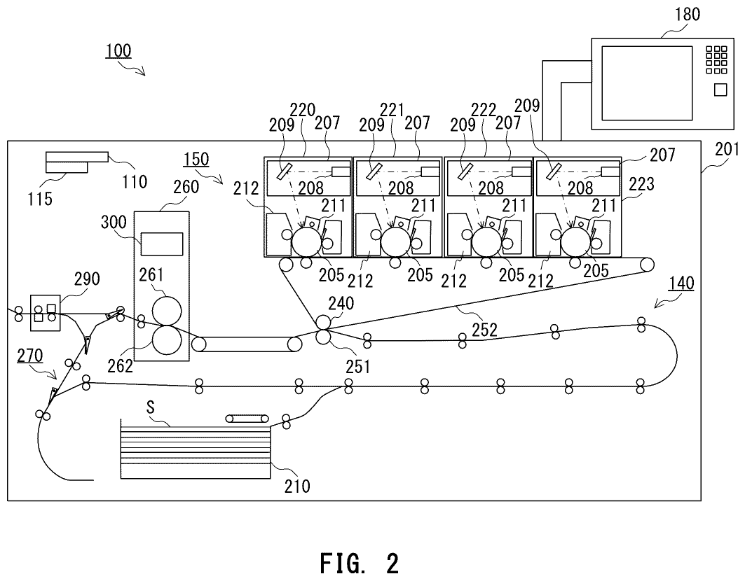

FIG. 2 is a configuration view of the image forming apparatus 100. The image forming apparatus 100 includes the operation panel 180 above a casing 201. Inside of the casing 201, the controller board 110, the storage 115, the sheet feeding unit 140, and the printer engine 150 illustrated in FIG. 1 are provided. The printer engine 150 includes mechanisms forming an engine unit, and an engine control unit for performing control of processing to be performed by each mechanism. The mechanisms forming the engine unit include an optical processing mechanism and a fixing processing mechanism. The optical processing mechanism is used for forming an electrostatic latent image, visualizing the electrostatic latent image, and transferring the visualized image onto a sheet S. The fixing processing mechanism fixes the toner image transferred onto the sheet S.

The image forming unit 152 of the printer engine 150 corresponds to the optical processing mechanism, and includes a Y station 220, an M station 221, a C station 222, a K station 223, an intermediate transfer belt 252, and a secondary transfer outer roller 251. The Y station 220, the M station 221, the C station 222, and the K station 223 have the same configuration, and only differ in colors of images to be formed. The Y station 220 forms a yellow image. The M station 221 forms a magenta image. The C station 222 forms a cyan image. The K station 223 forms a black image. The configuration of the Y station 220 is described here, and description of the configurations of the M station 221, the C station 222, and the K station 223 is omitted.

The Y station 220 includes a photosensitive drum 205, a charging device 211, an exposing device 207, and a developing device 212. The photosensitive drum 205 is a drum-shaped photosensitive member having a photosensitive layer on its surface. The charging device 211 uniformly charges the surface of the photosensitive drum 205 that rotates about a drum shaft. The exposing device 207 scans the charged surface of the photosensitive drum 205 with laser light modulated in accordance with the image data.

The exposing device 207 includes a laser driver which controls the emission of a semiconductor laser (not shown) in accordance with image data obtained from the CPU 114, a rotary polygon mirror 208, and a reflecting mirror 209. The laser light emitted from the semiconductor laser moves in a main scanning direction in accordance with the rotation of the rotary polygon mirror 208, and is guided by the reflecting mirror 209 to the surface of the photosensitive drum 205. The surface of the photosensitive drum 205 is exposed with light so that an electrostatic latent image is formed thereon.

The developing device 212 visualizes the electrostatic latent image with toner to form a toner image on the surface of the photosensitive drum 205. A yellow toner image is formed on the photosensitive drum 205 of the Y station 220. A magenta toner image is formed on the photosensitive drum 205 of the M station 221. A cyan toner image is formed on the photosensitive drum 205 of the C station 222. A black toner image is formed on the photosensitive drum 205 of the K station 223.

The intermediate transfer belt 252 is looped around rollers such as a secondary transfer inner roller 240, and rotates in the clockwise direction of FIG. 2. The toner images of the respective colors formed on the respective photosensitive drums 205 are transferred in a superimposing manner onto the rotating intermediate transfer belt 252. The toner image is transferred from the photosensitive drum 205 onto the intermediate transfer belt 252 by applying a bias voltage having a polarity reverse to that of the toner image to the intermediate transfer belt 252. In this manner, the intermediate transfer belt 252 bears a full-color toner image. The intermediate transfer belt 252 rotates to convey the borne toner image to a secondary transfer portion formed of the secondary transfer inner roller 240 and the secondary transfer outer roller 251.

The sheet feeding unit 140 corresponds to a feeding mechanism for the sheet S, and includes a storage unit 210 for storing the sheets S, conveyance paths, and conveying rollers. The sheet feeding unit 140 conveys the sheets S from the storage unit 210 one by one to the secondary transfer portion. The secondary transfer portion nips and conveys the intermediate transfer belt 252 and the sheet S by the secondary transfer inner roller 240 and the secondary transfer outer roller 251. At this time, a bias voltage having a polarity reverse to that of the toner image is applied to the secondary transfer outer roller 251 so that the toner image is transferred from the intermediate transfer belt 252 onto the sheet S.

The sheet S having the toner image transferred thereon is conveyed to the fixing unit 260 corresponding to the fixing processing mechanism. The fixing unit 260 includes a fixing roller 261, a pressure roller 262, and a circuit board 300. The fixing roller 261 incorporates a heat source. The pressure roller 262 is urged to the fixing roller 261 side. The circuit board 300 controls the fixing processing to be performed by the fixing unit 260. The fixing unit 260 nips and conveys the sheet S having the toner image transferred thereon by the fixing roller 261 and the pressure roller 262 so that the toner image is fixed to the sheet S. At this time, the fixing roller 261 heats and melts the toner image, and presses the sheet S between the fixing roller 261 and the pressure roller 262.

In the manner described above, the image is printed on the sheet S. In a case of duplex printing, the sheet S having the image printed on its first surface is re-conveyed to the secondary transfer portion via a reverse path 270. Through conveyance to the secondary transfer portion via the reverse path 270, an image forming surface of the sheet S is reversed. On the sheet S whose image forming surface has been reversed, an image is printed on a second surface different from the first surface by the secondary transfer portion and the fixing unit 260.

The sheet S having the image printed thereon passes through the image reading unit 290 provided on the downstream side of the fixing unit 260 in a conveying direction of the sheet so as to be discharged to the outside of the image forming apparatus 100. In a case where the image formed on the sheet S is the image for adjustment for adjusting the image forming condition, the image reading unit 290 is used for reading of this image for adjustment.

In order to perform the image forming processing as described above, the image forming apparatus 100 incorporates various actuators, such as motors and sensors. The actuators are each connected to a circuit board having electronic parts for control mounted thereon. Each electronic part mounted on the circuit board is electrically connected by a conductive wire. The circuit board according to the at least one embodiment of the present disclosure is, for example, a printed wiring board using, as the conductive wire, a wiring pattern formed by printed wiring lines.

The electronic part controls the operation of the actuator. A large number of circuit boards are thus provided in the image forming apparatus 100 so as to correspond to the actuators. One or more actuators are controlled by one circuit board. The circuit board is controlled by the CPU 114. The controller board 110 on which the CPU 114 is mounted is also an example of the circuit board. Hereinafter, the circuit board 300 provided in the fixing unit 260 is explained as an example of the circuit board.

### <Circuit Board>

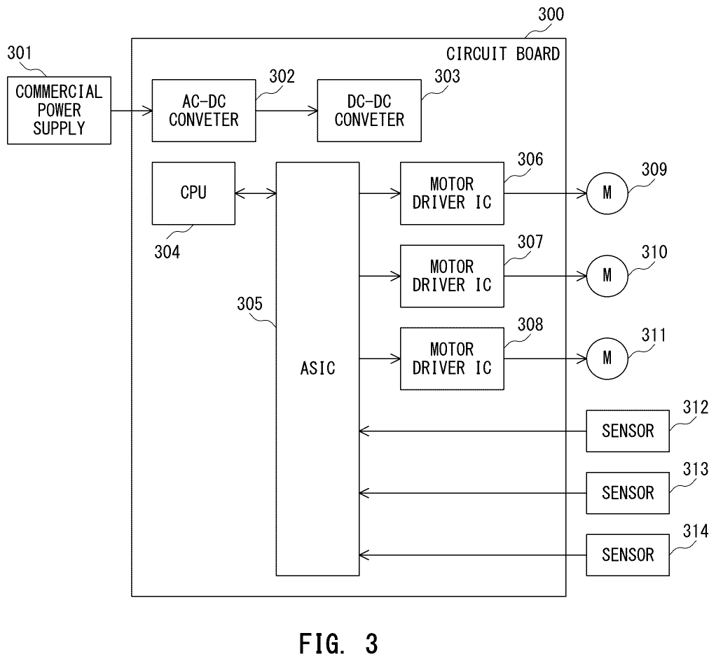

FIG. 3 is a functional block diagram of the circuit board 300 provided in the fixing unit 260. A plurality of motors 309 to 311 in the fixing unit 260 and a plurality of sensors 312 to 314 in the fixing unit 260 are electrically connected to the circuit board 300. The motor 309 is a drive source for driving the fixing roller 261 being a rotary member. The motor 310 is a drive source for urging the pressure roller 262 to the fixing roller 261 side. The motor 311 is a drive source for driving a roller being a rotary member for conveying the sheet S that has been subjected to the fixing processing to the downstream. The sensor 312 is a detector for detecting the sheet S that has been conveyed to the fixing unit 260. The sensor 313 is a temperature detector for detecting the temperature of the fixing roller 261. The sensor 314 is a detector for detecting the sheet S that has been subjected to the fixing processing.

The circuit board 300 implements various functions by a plurality of electronic parts. In the example of FIG. 3, the circuit board 300 includes an AC-DC converter 302 and a DC-DC converter 303. The AC-DC converter 302 is used for generating a predetermined DC voltage from an AC voltage. The DC-DC converter 303 converts a voltage value of the DC voltage. The circuit board 300 further includes a CPU 304, an application specific integrated circuit (ASIC) 305, and motor driver ICs 306 to 308, which are used for control of the actuators. On the circuit board 300, the plurality of integrated circuits (hereinafter referred to as “ICs”) and surrounding electronic parts corresponding to the ICs as described above are mounted as electronic parts.

The AC-DC converter 302 generates, from AC power supplied from a commercial power supply 301, a first power supply voltage which is a DC voltage having a predetermined voltage value. The DC-DC converter 303 generates, from the first power supply voltage supplied from the AC-DC converter 302, a second power supply voltage which is a DC voltage having a voltage value different from that of the first power supply voltage. The second power supply voltage generated by the DC-DC converter 303 is supplied to the CPU 304, the ASIC 305, and the like. The CPU 304 and the ASIC 305 operate by using the second power supply voltage supplied from the DC-DC converter 303. The first power supply voltage output from the AC-DC converter 302 is supplied to the electronic part and motors 309-311 which operate with a voltage value different from the voltage value for operating the CPU 304 or ASIC 305.

The CPU 304 is connected to each of the motor driver ICs 306 to 308 and each of the sensors 312 to 314 via the ASIC 305. The CPU 304 acquires detection results obtained by the sensors 312 to 314 to detect the state of the fixing unit 260 based on the detection results. The CPU 304 controls each of the motor driver ICs 306 to 308 via the ASIC 305 in accordance with the detected state of the fixing unit 260, to thereby control the drive of each of the motors 309 to 311. As described above, the CPU 304 and the ASIC 305 control the operation of the fixing unit 260.

The circuit board 300 is provided in the fixing unit 260 and thus controls the operation of the fixing unit 260, but other circuit boards provided in the image forming apparatus 100 similarly control operations of corresponding constituent parts. Each of the circuit boards in the image forming apparatus 100 (including the circuit board 300 and other circuit boards) is connected to the controller board 110 so that communication is allowed therebetween. Communication is allowed between circuit boards via the controller board 110. The circuit boards appropriately control the constituent parts in the image forming apparatus 100 while mutually sharing information on the detection results obtained by the sensors and the control states of the motors.

A large number of electronic parts are mounted on the circuit board. However, for some genuine electronic parts in the many regular electric parts, a situation may arise where procurement becomes difficult. In order to cope with the situation in which there is an electronic part that is difficult to procure, there is known a method of making research in advance for an electronic part having the same or similar shape and specification as each of the genuine electronic parts, as a replacement part. In a case where a problem occurs in part procurement, the replacement part may be procured and mounted on the circuit board so that the manufacture of the circuit board 300 is continued.

However, for example, in the case of the circuit board 300, a specific IC such as an IC of the DC-DC converter 303 or the motor driver IC 306, 307, or 308 may require a unique surrounding part in using the IC. Further, in some cases, there is no replaceable IC because the number of terminals, arrangement, array, or electrical specification of the IC is different. In this case, to cope with the situation in which the procurement of each electronic part becomes difficult, a different electronic part component having the same function as that of an electronic part component including each IC and its surrounding part is prepared. Those electronic part components are mounted on the circuit board in a mutually exclusive manner. With this coping method, a procurable IC is mounted depending on the availability of the mounting part, and hence the manufacture of the circuit board 300 can be continued.

The circuit board 300 of the at least one embodiment has a configuration capable of coping with the situation in which part procurement is difficult, and is further capable of reducing the area required for mounting. Now, description is given of a specific circuit configuration and wiring (conductor pattern) of the circuit board 300. In the at least one embodiment, description is given through use of a configuration of a motor driver IC for controlling a two-phase bipolar-drive stepping motor.

### <Electronic Part Component>

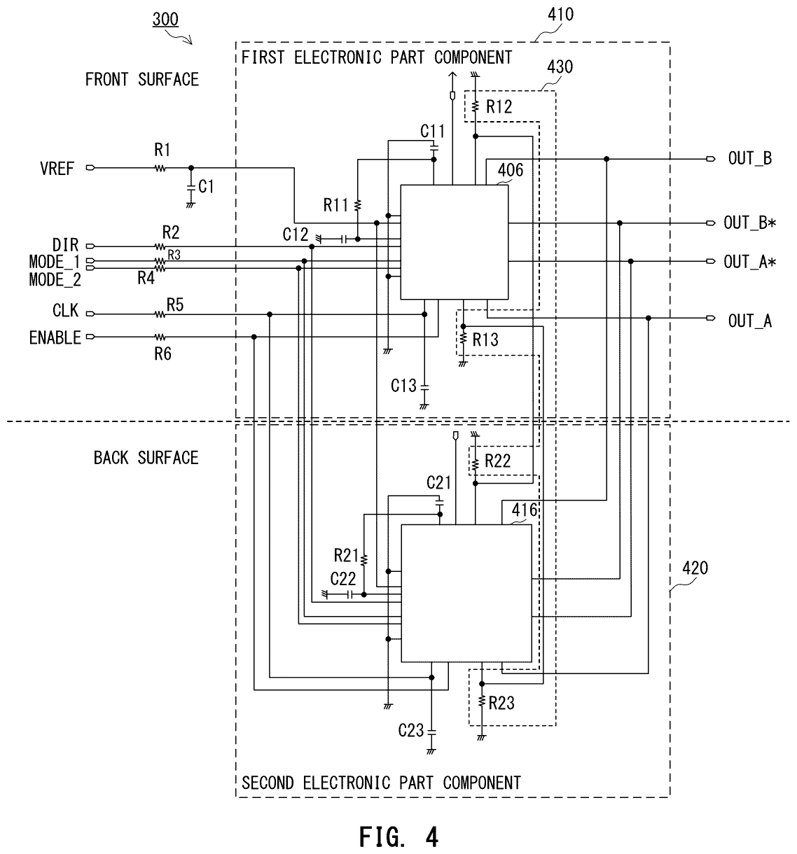

FIG. 4 is an explanatory view of electronic part components each including a motor driver IC and its surrounding electronic part. The electronic part components are a first electronic part component 410 including a motor driver IC 406, a second electronic part component 420 including a motor driver IC 416 which is a replacement product of the motor driver IC 406, and a shared electronic part component 430. The shared electronic part component 430 is shared by the motor driver ICs 406, 416. The first electronic part component 410 can be mounted on a first surface (front surface) of the circuit board 300. The second electronic part component 420 can be mounted on a second surface (back surface) different from the first surface of the circuit board 300. The first electronic part component 410 and the second electronic part component 420 are mounted on the circuit board 300 in a mutually exclusive manner.

The first electronic part component 410 includes resistor R11 and capacitors C11, C12, and C13 in addition to the motor driver IC 406. The resistor R11 and the capacitor C11 are components for determining a chopping frequency of constant-current pulse width modulation (PWM) control at the time of controlling a motor current. The capacitors C12, and C13 are each provided for noise removal. Similarly, the second electronic part component 420 includes resistor R21 and capacitors C21, C22, and C23 in addition to the motor driver IC 416. The resistor R21 and the capacitor 21 are the impedance for determining a chopping frequency of constant-current PWM control at the time of controlling a motor current. The capacitors C22, C23 are each provided for noise removal.

The shared electronic part component 430 includes current sense resistors R12, R13, R22, and R23. The current is detected based on the voltage at both ends of the current sense resistors R12, R13, R22, and R23. The current sense resistor R12 and the current sense resistor R22 are arranged at opposite positions on the front surface and the back surface. The current sense resistors R12 and R22 are connected in parallel through vias and are connected to current detection terminals that detect the phase B current of each motor driver IC 406 and 416 in the shortest distance.

That is, the circuit board 300 includes a wiring pattern that connects the current sense resistors R12 and R22 in parallel. The wiring pattern also includes a portion that connects the current sense resistors R12 and R22 to a connection portion to which the terminals of the motor driver IC 406 are connected and to a connection portion to which the terminals of the motor driver IC 416 are connected, respectively. Furthermore, in the at least one embodiment, the wiring pattern includes a via that penetrates the board. Similarly, current sense resistors R13 and R23 are disposed in positions opposite each other on the front surface and the back surface. The current sense resistors R13 and R23 are connected in parallel through vias, and are connected to current detection terminals that detect the A-phase current of each motor driver IC 406 and 416 in the shortest distance. The shared electronic part component 430 is an electronic part component that is always mounted, unlike the first electronic part component 410 and the second electronic part component 420, which are mounted in a mutually exclusive manner.

Control signals branched from the ASIC 305 via damping resistors R1 to R6 are input to the motor driver ICs 406 and 416. The control signals include an ENABLE signal, a CLK signal, a VREF signal, a MODE signal (MODE_1 signal and MODE_2 signal), and a DIR signal. The ENABLE signal is a control signal for enabling the output of the motor driver ICs 406 and 416. The CLK signal is a control signal for controlling a speed of the motor. The VREF signal is a control signal for controlling a value of current flowing through the motor. The MODE signal is a control signal for controlling an excitation pattern of the motor. The DIR signal is a control signal for controlling a rotation direction of the motor. The motor driver ICs 406 and 416 can drive the motor in accordance with an instruction obtained by those control signals. Phase output signals (OUT_A, OUT_A*, OUT_B, and OUT_B*) output from the motor driver ICs 406 and 416 are connected through vias in the shortest distance so as to be input to the motor. The operation of the motor is controlled by those signals input from the motor driver ICs 406 and 416.

In the description above, the first electronic part component 410 and the second electronic part component 420 are mounted on the circuit board 300 in a mutually exclusive manner. However, the circuit board 300 may have a configuration in which mounting is achieved in a mutually exclusive manner not in units of electronic part components but in units of ICs. For example, the motor driver IC 406 and the motor driver IC 416 may be mounted on the circuit board 300 in a mutually exclusive manner. In this case, for example, the resistor R11 and the capacitors C11, C12, and C13 may be shared by the motor driver IC 416, and the resistor R21 and the capacitors C21, C22, and C23 may be omitted.

### <Mounting Region of Circuit Board>

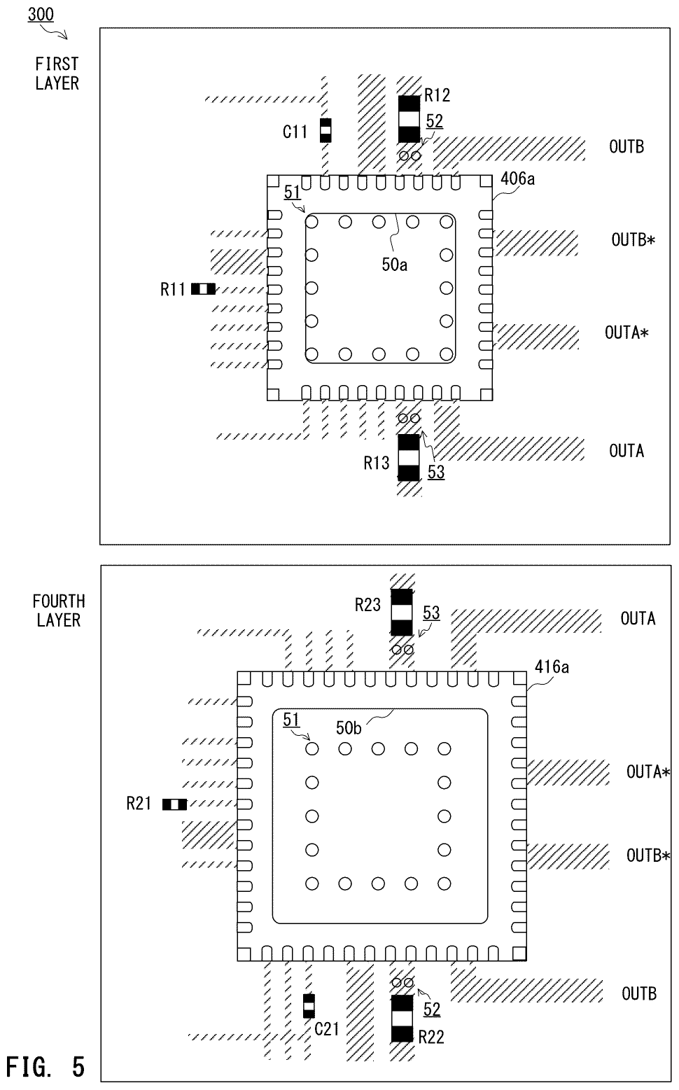

FIG. 5 is an explanatory view of wiring patterns in a region of the circuit board 300 in which the electronic part component is to be mounted. The circuit board 300 has a multilayer structure. In the at least one embodiment, the circuit board 300 has a four-layer structure in which the second layer is a power supply layer and the third layer is a ground layer. Description of wiring patterns of the second layer and the third layer is omitted. Electronic part components can be mounted on the first layer and the fourth layer. That is, the electronic part components are mounted on the outermost layer of the multilayer structure. The wiring pattern is formed using, for example, a printing technique through use of a conductor such as copper foil.

In the at least one embodiment, as described with reference to FIG. 4, the first electronic part component 410 and the second electronic part component 420 are provided on the front surface (first layer) and the back surface (fourth layer) of the circuit board 300 in a mutually exclusive manner. The current sense resistor R12 and the current sense resistor R22, which form the shared electronic part component 430, are mounted on a front surface (first layer) and a back surface (fourth layer) of the circuit board 300, respectively, and are connected to the motor driver ICs 406 and 416 in the shortest distance through a via 52. The current sense resistor R13 and the current sense resistor R23 also have the same configuration. It is noted that large current flows through the circuit pattern between the motor driver IC and the current sense resistor. Therefore, the circuit pattern through which the control signal which controls the motor driver IC described above is transmitted is preferably arranged away from the wiring pattern between the current sense resistors to prevent malfunction.

The first electronic part component 410 includes the motor driver IC 406. The second electronic part component 420 includes the motor driver IC 416 which is the replacement product of the motor driver IC 406. A mounting region 406a for the motor driver IC 406 on the front surface and a mounting region 416a for the motor driver IC 416 on the back surface are provided at the positions (coordinate regions) opposed to each other across the circuit board 300 (second layer and third layer). Wiring patterns are formed so that the motor driver ICs 406 and 416 can be mounted in those mounting regions 406a and 416a.

The first layer of the circuit board 300 is formed so that the motor driver IC 406 can be mounted in the mounting region 406a. The fourth layer of the circuit board 300 is formed so that the motor driver IC 416 can be mounted in the mounting region 416a. The motor driver IC 406 includes, on its back surface, a die pad 50a for supporting and fixing a semiconductor element. The motor driver IC 416 includes, on its back surface, a die pad 50b for supporting and fixing a semiconductor element.

The die pads 50a and 50b and a ground pattern of the circuit board 300 are connected to each other with solder so that heat of the motor driver ICs 406 and 416 is dissipated to the circuit board 300. Further, in a part of the circuit board 300 to be connected to the die pads 50a and 50b of the respective motor driver ICs 406 and 466, in order to enhance the heat dissipation effect, a plurality of common vias 51 for heat dissipation that are compatible with both of the motor driver ICs 406 and 416 are formed. That is, the plurality of vias 51 for heat dissipation are formed so as to pass through and connect the mounting region 406a and the mounting region 416a.

<Differences from Configuration of Comparative Example>

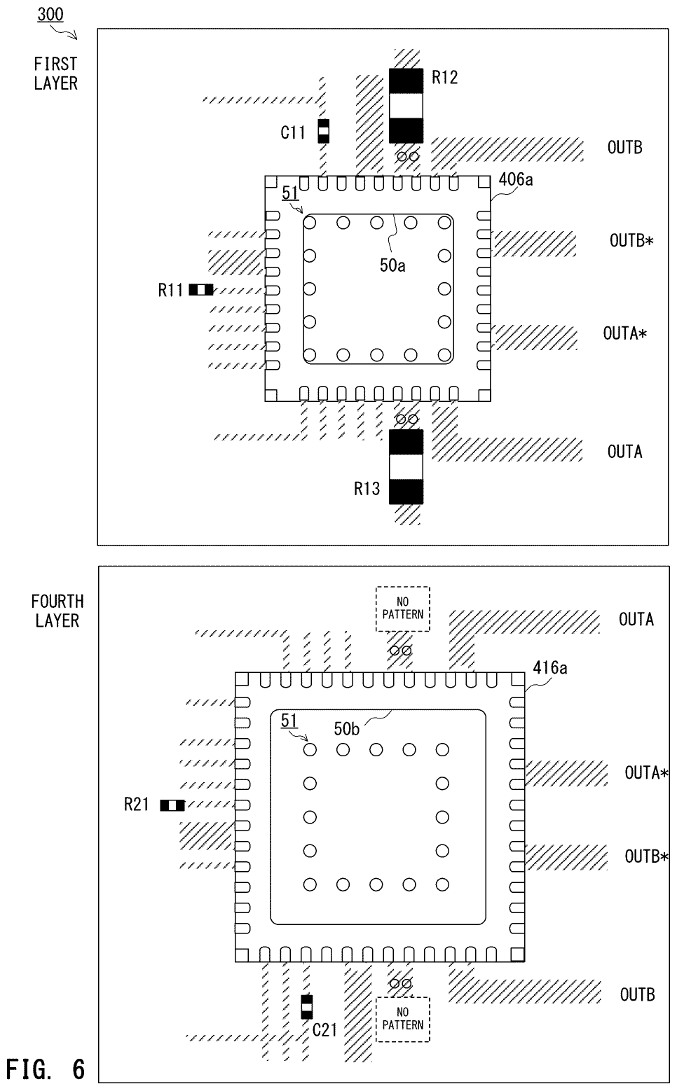

FIG. 6 is an explanatory view of wiring patterns in a region of the circuit board 300 of a comparative example in which the electronic part component is to be mounted. Comparing FIG. 5 and FIG. 6, the number and size of the current sense resistors are different. The comparative example also has a configuration in which the current sense resistor R12 and R13 are shared by motor driver ICs 406 and 416. However, in the comparative example, the current sense resistors R12 and R13 are arranged at one of a front surface (first layer) or a back surface (fourth layer), and are connected to the motor driver ICs 406 and 416 through via.

In this case, since a large current flows through the current sense resistors R12 and R13, it is necessary to select resistor elements with high wattage for the current sense resistors R12 and R13. Thus, the size of the current sense resistors R12 and R13 becomes large. For example, in a case where a motor is driven at 2 A (ampere), considering derating, current sense resistors with a resistance of 0.1Ω and 1 W, in a 5025 size are used. In addition, in the other side where the current sense resistors are not mounted, wasted space having no wiring pattern occurs.

As explained in FIG. 5, in the at least one embodiment, the current sense resistors R12, R13, R22, and R23 are divided into two groups, and the current sense resistors that belongs to one group are arranged on the front surface (first layer) and the current sense resistors that belongs to the other group are arranged on the back surface (fourth layer). This eliminates wasted space and minimizes the substrate area by increasing the mounting density.

Specifically, resistor elements with a resistance of 0.2Ω and 0.5 W, in a 3216 size are adopted as the current sense resistors R12, R13, R22, and are divided and arranged on the front surface (first layer) and the back surface (fourth layer). The wiring pattern is provided so that the composite resistance is 0.1Ω by connecting the current sense resistor R12 and the current sense resistor R22 in parallel. The current sense resistors R12 and R22 are connected to the motor driver ICs 406 and 416 through the via 52, resulting in the shortest connection. By connecting the resistors in parallel, the current flowing through one of the current sense resistors is 1 A. This enables the use of resistor elements of 0.5 W, in the 3216 size, thus reducing the board area for current detection by about 60% compared to the comparative configuration. The same applies to the current sense resistors R13 and R23.

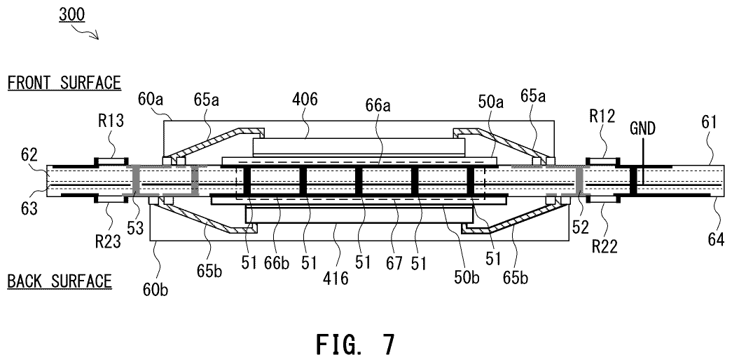

FIG. 7 is a cross-sectional view of a part of the circuit board 300 in which the motor driver IC and the current sense resistor are mounted. As described above, the circuit board 300 in the at least one embodiment includes four layers of a first layer 61, a second layer 62, a third layer 63, and a fourth layer 64. The circuit board 300 is a double-sided reflow board, and electronic parts (electronic part components) are mounted on the first layer 61 and the fourth layer 64.

As described above, the first electronic part component 410 including the motor driver IC 406 is mounted on the first layer 61 corresponding to the front surface, and the second electronic part component 420 including the motor driver IC 416 is mounted on the fourth layer 64 corresponding to the back surface. The first electronic part component 410 and the second electronic part component 420 are mounted in a mutually exclusive manner. The current sense resistors R12 and R13 that constitute the shared electronic part component 430 are mounted on the first layer 61, which is the front surface, and the current sense resistors R22 and R23 are mounted on the fourth layer 64, which is the back surface, respectively. In other words, the shared common electronic part component 430 and either one of the first electronic part component 410 and the second electronic part component 420 are mounted on the circuit board 300.

The current sense resistor R12 and the current sense resistor R22 are arranged at opposite positions on the first layer 61 and the fourth layer 64 (front surface and back surface). The current sense resistors R12 and R22 are connected to the motor driver ICs 406 and 416 through the via 52 in parallel. The current sense resistor R13 and the current sense resistor R23 are arranged at opposite positions on the front surface and back surface. The current sense resistors R13 and R23 are connected to the motor driver ICs 406 and 416 through the via 53 in parallel.

The motor driver IC 406 is a semiconductor device which is covered by a case 60a and is to be mounted on the die pad 50a. The motor driver IC 406 is bonded by wires 65a in the case 60a. The motor driver IC 416 is a semiconductor device which is covered by a case 60b and is to be mounted on the die pad 50b. The motor driver IC 416 is bonded by wires 65b in the case 60b.

The second layer 62 is the power supply layer. The second layer 62 includes wiring lines for supplying power to the motor driver ICs 406 and 416 and wiring lines for supplying a low voltage for driving a logic circuit, such as a CPU or an ASIC. The third layer 63 is the ground (GND) layer, and is connected to ground patterns of the first layer 61 and the fourth layer 64 through vias. The third layer 63 provides a ground voltage to the first layer 61 and the fourth layer 64.

A plurality of vias surrounded by a broken line 67 are the vias 51 for heat dissipation, and are formed to enhance the heat dissipation effect of the motor driver ICs 406 and 416. The vias 51 for heat dissipation can be brought into contact with the die pads 50a and 50b of both of the motor driver IC 406 and the motor driver IC 416, and are shared by the motor driver ICs 406 and 416. Heat of the motor driver IC 406 and the motor driver IC 416 is dissipated by the vias 51 for heat dissipation via the die pads 50a and 50b.

The vias 51 for heat dissipation and the die pad 50a are brought into contact with each other through intermediation of a wiring pattern 66a for heat dissipation. The vias 51 for heat dissipation and the die pad 50b are brought into contact with each other through intermediation of a wiring pattern 66b for heat dissipation. The wiring pattern 66a for heat dissipation is formed on the first layer 61 so as to come into contact with the entire surface of the die pad 50a. The wiring pattern 66b for heat dissipation is formed on the fourth layer 64 so as to come into contact with the entire surface of the die pad 50b. The wiring patterns 66a and 66b for heat dissipation come into contact with the entire surfaces of the respective die pads 50a and 50b to enhance the heat dissipation efficiency.

On the front surface and back surface of the circuit board 300 configured as described above, some of electronic parts (semiconductor devices) such as ICs, or electronic part components including a plurality of electronic parts, each for implementing the same function, are mounted in a mutually exclusive manner. Since the remaining electronic part components are always mounted on the front surface and the back surface, a board area is suppressed to the minimum. With this configuration, even if it becomes difficult to procure genuine parts, the manufacture of the circuit board 300 can be continued using replacement products.

In the at least one embodiment, the motor driver ICs 406 and 416, as examples of the electronic parts (semiconductor devices), and the current sense resistors R12, R13, R22, and R23, as examples of the surrounding electronic parts of the electronic parts, are described, however, the electronic parts (semiconductor devices) and the surrounding electronic parts are not limited thereto. If the functions of the electronic part components can be divided and mounted, their functions are not limited. The electronic parts (semiconductor devices) may be, for example, DC-DC converters, switching ICs, field effect transistors (FETs), etc. The electronic elements that are used as peripheral electronic parts may be capacitors for charge pumps, power inductors for smoothing, etc.

According to the at least one embodiment of the present disclosure, a circuit board capable of mounting multiple electronic parts can be provided.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-151594, filed Sep. 3, 2024, which is hereby incorporated by reference herein in its entirety.

What is claimed is:

1. A circuit board comprising:
a first surface including a first region in which a first electronic part is mountable;
a second surface, which is different from the first surface, including a second region in which a second electronic part is mountable;
a first connection portion which is arranged on the first surface and to which a terminal of the first electronic part is connected;
a first element arranged on the first surface;
a second connection portion which is arranged on the second surface and to which a terminal of the second electronic part is connected;
a second element arranged on the second surface;
a wiring pattern that connects the first element and the second element in parallel, and electrically connects both of the first element and the second element to the first connection portion and to the second connection portion.

2. The circuit board according to claim 1,
wherein the first electronic part and the second electronic part are mounted on the circuit board in a mutually exclusive manner.

3. The circuit board according to claim 1,
wherein a position on the first surface where the first element is mounted and a position on the second surface where the second element is mounted are overlap with each other in opposite sides with respect to the circuit board therebetween.

4. The circuit board according to claim 1,
wherein the circuit board has a multilayer structure,
wherein the first surface and the second surface are outermost layers of the multilayer structure, and
the first element and the second element are connected by a via that penetrates the circuit board from the first surface to the second surface.

5. The circuit board according to claim 4,
wherein, in the first region, a first semiconductor device configured to drive a motor is mountable as the first electronic part, and
wherein, in the second region, a second semiconductor device configured to drive the motor is mountable as the second electronic part.

6. The circuit board according to claim 5,
wherein the first element includes a resistor configured to sense current flowing through the first electronic part, and
wherein the second element includes a resistor configured to sense current flowing through the second electronic part.

7. The circuit board according to claim 1, wherein the second electronic part is a replacement product of the first electronic part.

8. The circuit board according to claim 1,
wherein a first electronic part component comprising the first electronic part and the first element is mountable on the first surface, and
wherein a second electronic part component comprising the second electronic part and the second element is mountable on the second surface.

9. An image forming apparatus comprising
a circuit board; and
an image forming part configured to perform a function related or included in forming image,
wherein the circuit board includes:
a first surface including a first region in which a first electronic part is mountable;
a second surface, which is different from the first surface, including a second region in which a second electronic part is mountable;
a first connection portion which is arranged on the first surface and to which a terminal of the first electronic part is connected;
a first element arranged on the first surface;
a second connection portion which is arranged on the second surface and to which a terminal of the second electronic part is connected;
a second element arranged on the second surface; and
a wiring pattern that connects the first element and the second element in parallel, and electrically connects both of the first element and the second element to the first connection portion and to the second connection portion, and
wherein the image forming part is configured to be controlled by one of the first electronic part or the second electronic part mounted on the circuit board.

10. The image forming apparatus according to claim 9,
wherein the image forming part includes a motor,
wherein the first electronic part includes a semiconductor device configured to drive the motor, and
wherein the second electronic part includes a semiconductor device configured to drive the motor.

11. The image forming apparatus according to claim 9,
wherein the first element includes a resistor configured to sense current flowing through the first electronic part, and
wherein the second element includes a resistor configured to sense current flowing through the second electronic part.
